(19) United States
(12) Patent Application Publication
(10) Pub. No.: US 2018/0240684 A1
(43) Pub. Date: Aug. 23, 2018

(54) SUBSTRATE PROCESSING APPARATUS AND SUBSTRATE PROCESSING METHOD

(71) Applicant: Tokyo Electron Limited, Tokyo (JP)

(72) Inventors: Koji Egashira, Koshi-shi, Kumamoto (JP); Masami Yamashita, Koshi-shi, Kumamoto (JP); Yoshiyuki Honda, Koshi-shi, Kumamoto (JP); Yuki Yoshida, Koshi-shi, Kumamoto (JP); Yosuke Kawabuchi, Koshi-shi, Kumamoto (JP)

(21) Appl. No.: 15/764,482

(22) PCT Filed: Sep. 29, 2016
(86) PCT No.: PCT/JP2016/078903

§ 371 Date: Mar. 29, 2018

(30) Foreign Application Priority Data
Sep. 30, 2015 (JP) 2015-193550
Jun. 23, 2016 (JP) 2016-124672

(51) Int. Cl. H01L 21/67; H01L 21/02; H01J 37/32

(52) U.S. Cl. CPC H01L 21/67034; H01L 21/02101; H01J 2237/335; H01J 37/32449; H01J 37/32715

(57) ABSTRACT

A gas discharge hole 74 (205) configured to discharge a gas is provided at a position outside an edge of a substrate W held by a substrate holding unit 89 (204) within a processing chamber 81 (201). The gas discharged from the gas discharge hole 74 (205) forms a flow of the gas flowing in a direction along a first surface (front surface) of the substrate held by the substrate holding unit. A gas of a sublimation substance which is sublimated and a foreign substance included in the gas are flown along the flow of the gas to be removed from a vicinity of the substrate. The gas serves as a heat transfer medium for heat transfer from a heating unit 88 (203) to the substrate.

### TECHNICAL FIELD

The various embodiments described herein pertain generally to a technique of sublimating a sublimation substance adhering to a substrate.

### BACKGROUND ART

In the course of manufacturing a semiconductor device, a chemical liquid processing such as a wet etching processing or a cleaning processing is performed by supplying a chemical liquid onto a substrate such as a semiconductor wafer. After the chemical liquid processing, a rinsing processing and a scattering and drying processing are performed. As a pattern formed on the substrate is miniaturized with a high aspect ratio, the pattern is highly likely to be damaged due to a surface tension of the liquid which tends to move out from the inside of a pattern recess during the drying processing. Recently, to cope with this problem, the drying processing is performed by using a sublimation substance after the rinsing processing (see, for example, Patent Document 1). The drying processing using the sublimation substance includes a process of replacing a rinse liquid or a solvent filling the pattern recess with a sublimation substance solution, a process of solidifying the sublimation substance solution, and a process of sublimating the sublimation substance.

During or immediately after the sublimating process, however, a foreign substance originated from the sublimation substance once separated from the substrate may attach or reattach to a surface of the substrate, resulting in contamination of the surface of the substrate.

### REFERENCES

Patent Document 1: Japanese Patent Laid-open Publication No. 2012-243869

### SUMMARY OF THE INVENTION

In view of the foregoing, exemplary embodiments provide a technique of suppressing a substrate from being contaminated by a foreign substance originated from a sublimation substance once separated from the substrate during or immediately after a sublimation processing.

In an exemplary embodiment, there is provided a plasma processing apparatus including a substrate holding unit configured to hold a substrate having a first surface on which a sublimation substance is coated and a second surface opposite to the first surface; a processing chamber in which the substrate held by the substrate holding unit is accommodated; a heating unit configured to heat an inside of the processing chamber to sublimate the sublimation substance coated on the first surface of the substrate; and a gas supply unit configured to supply a gas into the processing chamber. The gas supply unit includes a gas discharge hole configured to discharge the gas, and the gas discharge hole is provided at a position outside an edge of the substrate held by the substrate holding unit and forms a flow of the gas flowing in a direction along the first surface or the second surface of the substrate held by the substrate holding unit.

In another exemplary embodiment, there is provided a substrate processing method including placing, in a processing chamber, a substrate having a first surface on which a sublimation substance is coated and a second surface opposite to the first surface; heating the substrate to sublimate the sublimation substance coated on the first surface of the substrate; and forming, by discharging a gas from a gas discharge hole provided at a position outside an edge of the substrate within the processing chamber, a flow of the gas in a direction along the first surface or the second surface of the substrate placed in the processing chamber.

According to the exemplary embodiments, the gas of the sublimation substance, which is sublimated to be separated from the substrate, is removed from the space near the substrate by the flow of the gas discharged from the gas discharge hole. Accordingly, the attachment or the reattachment of the foreign substance originated from the sublimation substance to the substrate can be suppressed.

### BRIEF DESCRIPTION OF THE DRAWINGS

FIG. 1 is a schematic side view illustrating an overall configuration of a sublimation processing system according to an exemplary embodiment of the substrate processing apparatus.

FIG. 2 is a longitudinal sectional side view of a sublimation processing unit.

FIG. 3 is a cross sectional view taken along a line III-III of FIG. 2.

FIG. 4 is a transversal sectional plan view of the sublimation processing unit having a wafer supporting member according to a modification example.

FIG. 5 is a transversal sectional plan view of the sublimation processing unit having a gas supply unit according to a modification example.

FIG. 6 is a schematic diagram illustrating a gas supply pipe shown in FIG. 5.

FIG. 7 is a longitudinal sectional side view of the sublimation processing unit in which an electric dust collecting device is provided at a rear side of a processing chamber of the sublimation processing unit.

FIG. 8 is a schematic diagram for describing a sublimation processing method according to another exemplary embodiment.

FIG. 9 is a graph for describing an influence of a gas supply upon a temperature rise of a wafer.

### DETAILED DESCRIPTION

Hereinafter, exemplary embodiments will be described with reference to the accompanying drawings.

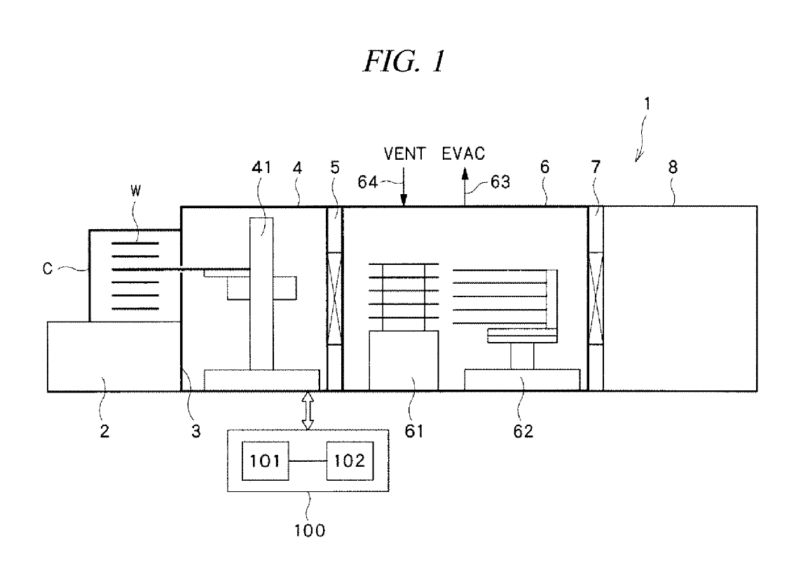

FIG. 1 is a schematic side view illustrating an overall configuration of a sublimation processing system 1 (substrate processing apparatus). The sublimation processing system 1 includes a load port (carry-in/out station) 2, an atmospheric transfer chamber 4, a load lock chamber 6 and a sublimation processing unit 8.

The load port 2 is configured to mount thereon a substrate transfer container C, e.g., a FOUP, accommodating therein multiple wafers W.

An internal space of the atmospheric transfer chamber 4 is set to be in an atmospheric atmosphere, the same as a clean room. A first wafer transfer mechanism 41, here, a single-wafer type transfer robot configured to transfer the wafers W sheet by sheet is provided within the atmospheric transfer chamber 4. Here, however, the first wafer transfer mechanism 41 may be a batch type transfer robot. A lid of the substrate transfer container C is opened by a non-illustrated lid opening/closing device provided at a wall 3 which separates the load port 2 from the atmospheric transfer chamber 4, and the wafer W can be taken out by the first wafer transfer mechanism 41.

Provided within the load lock chamber 6 are a buffer shelf 61 on which a multiple number of wafers W can be placed; and a second wafer transfer mechanism 62, here, a batch type transfer robot configured to transfer the multiple number of wafers W at the same time. The lock chamber 6 can be turned into a decompressed atmosphere having the same vacuum level as that of the sublimation processing unit 8 by being evacuated through a vacuum evacuation line 63, and can also be turned into the atmospheric atmosphere by introducing atmosphere through a vent line 64.

A gate valve 5 is provided between the atmospheric transfer chamber 4 and the load lock chamber 6, and a gate valve 7 is provided between the load lock chamber 6 and the sublimation processing unit 8.

The sublimation processing system 1 is equipped with a control device 100. The control device 100 is implemented by, by way of non-limiting example, a computer and is equipped with a control unit 101 and a storage unit 102. The storage unit 102 stores therein programs for controlling various types of processings performed in the sublimation processing system. The control unit 101 controls operations of the sublimation processing system by reading and executing the programs stored in the storage unit 102.

Further, the programs are stored in a computer-readable recording medium and may be installed to the storage unit 102 of the control device 100 from the recording medium. The computer-readable recording medium may be implemented by, by way of example, but not limitation, a hard disk HD, a flexible disk FD, a compact disk CD, a magnet optical disk MO, a memory card, or the like.

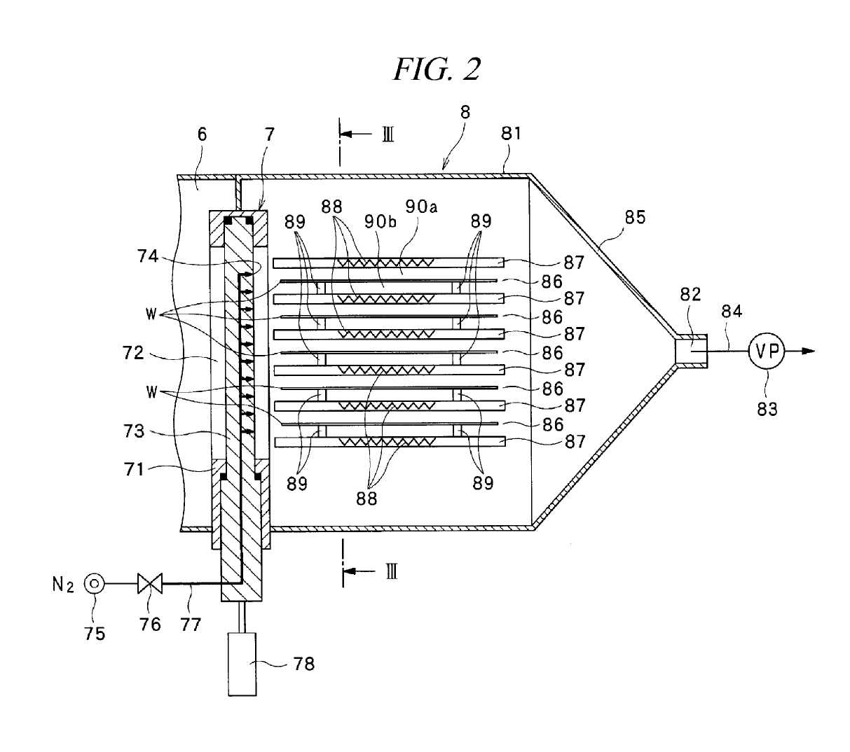

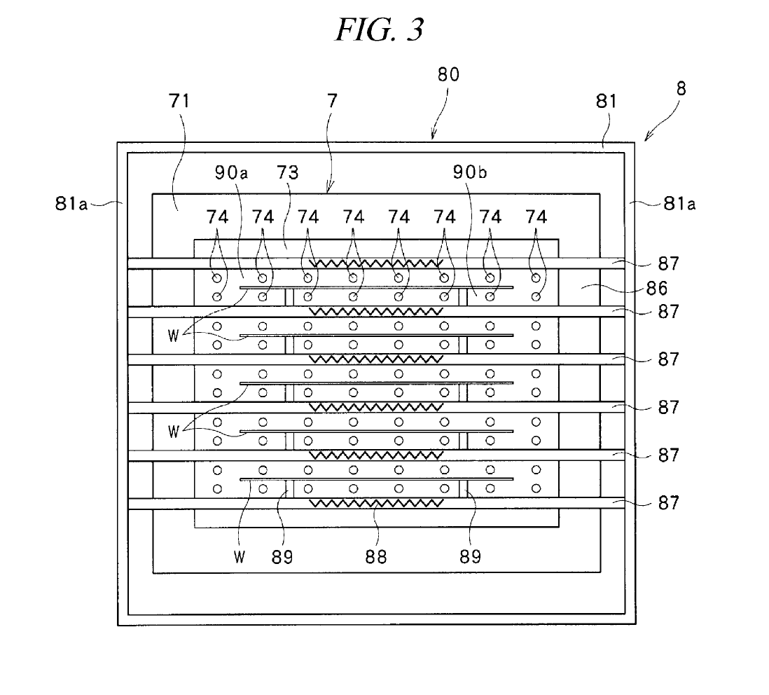

A configuration of the sublimation processing unit 8 will be elaborated below with reference to FIG. 2 and FIG. 3. The sublimation processing unit 8 has a processing chamber (sublimation processing chamber) 81. A gas exhaust port 82 is provided at a rear surface of the processing chamber 81, and a gas exhaust line 84 provided with a vacuum pump 83 (e.g., a turbo molecular pump) is connected to the gas exhaust port 82.

A wall at a rear side of the processing chamber 81 is formed as a gas guiding wall 85 having a taper shape in which a cross sectional area thereof is gradually decreased toward the gas exhaust port 82. By way of example, the gas guiding wall 85 may be formed to have a funnel shape of a substantially quadrangular pyramid form.

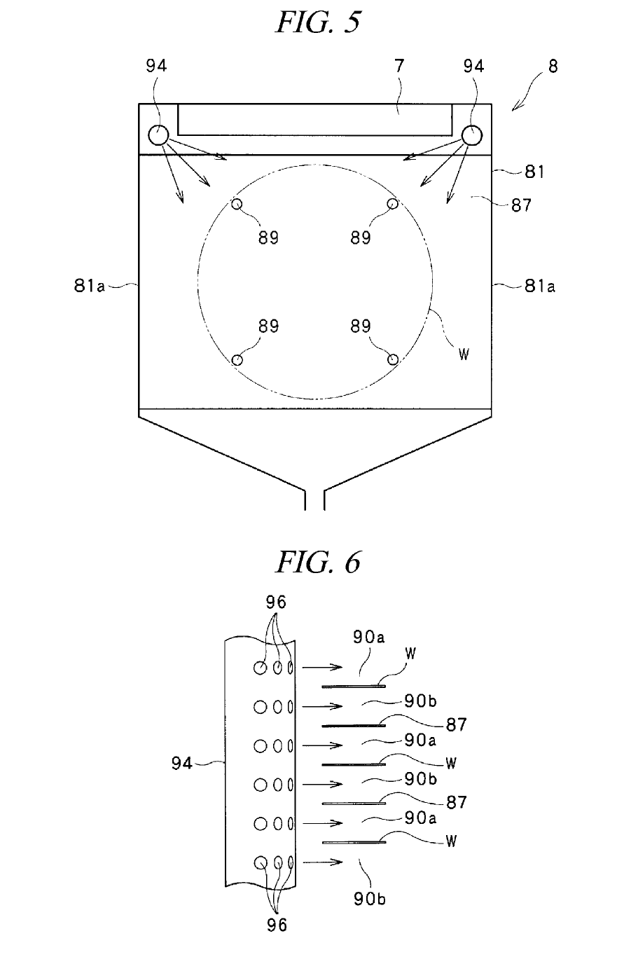

A plurality of partition plates 87 are provided within the processing chamber 81. These partition plates 87 partition an internal space of the processing chamber 81 into vertically separated multiple sections 86 (that is, the multiple sections 86 isolated from each other in a thickness direction of the wafer W, i.e., in an arrangement direction of the wafers W). Desirably, each partition plate 87 has an area larger than the wafer W, and, when viewed from above the wafer W, an outline of the wafer W is completely included in an outline of the partition plate 87 (see FIG. 5). Both ends of the partition plate 87 in a transversal direction are connected to sidewalls 81a of the processing chamber 81.

Each partition plate 87 is equipped with a heater (heating unit) 88 configured to heat the wafer W. Accordingly, each partition plate 87 also has a function as a heat plate.

Each partition plate 87 is also provided with wafer supporting members (substrate holding unit) 89 in the form of supporting pins configured to support a rear surface (second surface) of the wafer W from below. The wafer supporting members 89 support a single sheet of wafer W within the section 86 between the vertically adjacent partition plates 87. Here, provided between each wafer W and the partition plate 87 disposed thereabove and between the corresponding wafer W and the partition plate 87 thereunder, are a gap 90a and a gap 90b, which serve as gas passages, respectively (reference numerals are only assigned to those in the uppermost section).

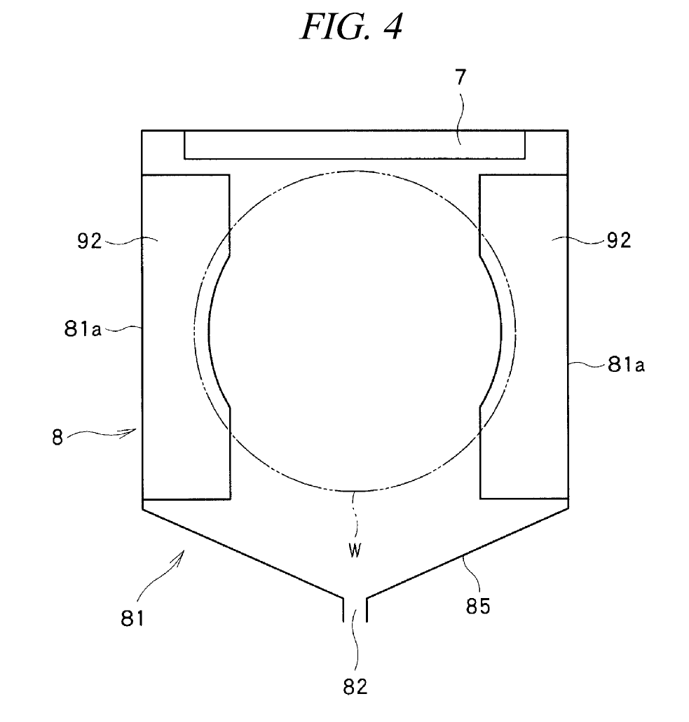

Instead of providing the wafer supporting members 89 in the form of the supporting pins provided on a top surface of each partition plate 87, wafer supporting members horizontally protruded from the two opposite sidewalls 81a of the processing chamber 81 toward a central portion of the internal space of the processing chamber 81 may be arranged in multiple levels in the form of shelves (see FIG. 4).

The aforementioned gate valve 7 is provided at a front surface of the processing chamber 81. The gate valve 7 includes: a valve main body 71 having an opening 72 of a size through which a wafer holder of the second wafer transfer mechanism 62 configured to transfer the multiple number of wafers W at the same time can pass; and a movable valve body 73 configured to be driven by an actuator 78 to close the opening 72 of the valve main body 71. Each of the opening 72 and the valve body 73 has, for example, a rectangular shape.

A multiple number of gas discharge holes 74 for discharging a purge gas (e.g., a nitrogen gas) is formed at a surface of the valve body 73 of the gate valve 7 facing the processing chamber 81. The purge gas is supplied from a purge gas supply source 75 to the gas discharge holes 74 through a gas line 77 which is provided with an opening/closing valve 76. The valve body 73 having the gas discharge holes 74 and the members 75, 76 and 77 constitute a gas supply unit.

In FIG. 3, the reference numeral 74 is only assigned to the gas discharge holes corresponding to the uppermost section 86, for the simplicity of illustration. The gas discharge holes 74 discharge the gas toward the gap 90a between each wafer W and the partition plate 87 thereabove and the gap 90b between the corresponding wafer W and the partition plate 87 thereunder. The purge gas discharged into the gap 90a and the gap 90b is flown toward the gas exhaust port 82.

It is desirable to provide the gas discharge holes 74 such that flow rates of the purge gas flowing in the respective gaps 90a and 90b (the respective sections 86) are substantially same and, also, such that flows of the purge gas formed within the individual gaps 90a and 90b are uniformly distributed in a width direction of the wafer (in the left-right direction of FIG. 3). Though a gas of a sublimation substance needs to be purged only from the gap 90a, it is desirable that the gas flows within the gap 90b at the same flow velocity as that in the gap 90a for the sake of smooth flow of the gas within the processing chamber 81.

To elaborate, the gas discharge holes 74 may be arranged in a substantially grid-like pattern, as illustrated in FIG. 3, for example. In this case, for every single gap 90a (90b), multiple gas discharge holes 74 may be arranged at a regular interval in a horizontal direction within a range equal to or larger than the width (diameter) of the wafer W.

To uniform a flow rate of the purge gas discharged from the individual gas discharge holes 74, a gas buffer room (not shown), which may be the same as one provided at a shower head of a CVD apparatus, may be provided within the valve body 73, and the purge gas may be distributed to the individual gas discharge holes 74 via the gas buffer room.

To allow the purge gas to flow smoothly in the gaps 90a and 90b, it is desirable that an end of each partition plate 87 at the gate valve 7 side is located as close to the closed valve body 73 as possible.

Further, in the shown exemplary embodiment, the sublimation processing unit 8 is configured to accommodate five sheets of wafers W at one time. However, it is apparent that the sublimation processing unit 8 may be configured to accommodate a larger number (e.g., 25 sheets) or a smaller number of wafers W at one time.

Now, an operation of the sublimation processing system 1 will be explained. The operation to be described below is automatically performed under the control of the control device 100. At this time, the control device 100 executes the control program stored in the storage unit 102 and controls the individual constituent components of the sublimation processing system 1 to be operated to implement processing parameters defined in processing recipes stored in the storage unit 102.

First, the substrate transfer container C accommodating therein multiple wafers W, each of which has a front surface (device formation surface) on which a sublimation substance is coated, is carried into the load port 2. A pattern having an irregularity is formed on the front surface (first surface) of each wafer W, and a film of the sublimation substance in a solid state is previously formed on the front surface of the wafer W including the inside of the recess of the pattern. Such a film of the sublimation substance may be formed by a commonly known method (for example, a method disclosed in Japanese Patent Laid-open Publication No. 2012-243869 filed by the applicant of the present application).

In a typical operation mode of the sublimation processing system 1, the inside of the processing chamber 81 of the sublimation processing unit 8 is evacuated through the gas exhaust port 82 to be always maintained in a decompressed atmosphere (e.g., 10 Pa or below). Further, the heaters 88 provided at the partition plates 87 are already operated before the wafers W are carried into the processing chamber 81, so that the inside of the processing chamber 81 is previously heated to a preset temperature (e.g., 150° C. to 200° C.). The internal pressure and the internal temperature of the processing chamber 81 are determined based on the kind of the sublimation substance on the wafer W.

If the substrate transfer container C is placed on the load port 2, the load lock chamber 6 is turned into the atmospheric atmosphere, and the gate vale 5 is opened in the state that the gate valve 7 is closed. The first wafer transfer mechanism 41 within the atmospheric transfer chamber 4 takes out a wafer W from the substrate transfer container C the non-illustrated lid of which is opened, and transfers the wafer W onto the buffer shelf 61 within the load lock chamber 6.

If a preset number of wafers W are placed on the buffer shelf 61, the gate valve 5 is closed in the state that the gate valve 7 is closed, and the load lock chamber 6 is evacuated into the decompressed atmosphere of the same vacuum level as that of the processing chamber 81 of the sublimation processing unit 8.

Thereafter, the gate valve 7 is opened while the gate valve 5 is kept closed. The second wafer transfer mechanism 62 within the load lock chamber 6 takes all the wafers W placed on the buffer shelf 61 at one time and places the wafers W on the wafer supporting members 89 within the processing chamber 81. At this time, each wafer W is placed with the front surface (the first surface as the device formation surface) thereof facing upwards. Then, the gate valve 7 is closed, and a sublimation processing by the sublimation processing unit 8 is begun.

The wafer W placed on the wafer supporting members 89 is heated to a temperature higher than a sublimation temperature of the sublimation substance on the wafer W by heat generated from the heater 88, so that the sublimation substance is sublimated to be turned into a gas phase.

At this time, within the processing chamber 81, there is formed a flow of the purge gas (flowing from the left side toward the right side of FIG. 2) flowing toward the gas exhaust port 82 through the gaps 90a and 90b after being discharged from the gas discharge holes 74 of the valve body 73 of the gate valve 7 provided at an outside of edges of the wafers W. Accordingly, the gas of the sublimation substance is flown along the flow of the purge gas to be exhausted from the inside of the processing chamber 81.

If the sublimation substance is completely removed from the wafers W with a lapse of a predetermined time, the gate valve 7 is opened while the gate valve 5 is kept closed. Then, the second wafer transfer mechanism 62 takes all the wafers W from the processing chamber 81 at one time and places the taken wafers W on the buffer shelf 61 within the load lock chamber 6 which is set to be in the decompressed atmosphere.

Subsequently, the gate valve 7 is closed while the gate valve 5 is kept closed, and the load lock chamber 6 is turned into the atmospheric atmosphere. Thereafter, the gate valve 5 is opened, and the first wafer transfer mechanism 41 returns the wafers W on the buffer shelf 61 back into the substrate transfer container C, and the series of operations are ended.

According to the above-described exemplary embodiment, while the sublimation processing is performed, the purge gas flows near the front surface (first surface) of each wafer W in a direction along the corresponding front surface of the wafer W within the processing chamber 81. Accordingly, the sublimation substance sublimated from the front surface of the wafer W is rapidly discharged out of the processing chamber 81 along the flow of the purge gas. Therefore, the gas of the sublimation substance hardly stays near the wafer W. Thus, it is possible to suppress or prevent contamination of the wafer W caused as the sublimation substance, which is once separated from the wafer W by the sublimation, or a foreign substance originated from the separated sublimation substance such as a foreign substance, which is included in the sublimation substance and discharged near the wafer with the sublimation of the sublimation substance, is reattached to the same wafer W or attached to another wafer W. Further, a generation amount of the gas of the sublimation substance is not maintained constant after the heating is begun, but is increased as the temperature of the wafer W rises. Then, if the sublimation progresses to some extent and the amount of the sublimation substance on the wafer W is decreased, the generation amount of the gas of the sublimation substance is decreased. Accordingly, it may be desirable to increase the supply amount of the purge gas in response to the increase of the generation amount of the gas of the sublimation substance to set the supply amount of the purge gas to reach the maximum when the generation amount of the gas of the sublimation substance is maximum. Further, afterwards, as the end of the sublimation processing is approaching, the generation amount of the gas is decreased, so that the supply amount of the purge gas may be reduced. For the purpose, an experiment may be conducted to investigate a variation of the generation amount of the gas of the sublimation substance with a lapse of time, and a timing for changing the supply amount of the purge gas may be determined based on the result of this experiment to be stored in the control device 100. During the drying processing, the control device 100 may control the opening/closing valve 76 or a non-illustrated flow rate controller provided at the gas line 77 based on the stored timing.

When the second wafer transfer mechanism 62 enters the processing chamber 81 after the sublimation processing is ended, the wafer holder of the second wafer transfer mechanism 62 is at a room temperature. Therefore, if a large amount of the sublimation substance in the gas phase exists in the processing chamber 81, this sublimation substance may be solidified and fall down as particles, so that the wafer W may be contaminated. Furthermore, if moisture (vapor) exists within the processing chamber 81 when the second wafer transfer mechanism 62 enters the processing chamber 81, the condensation of this moisture may occur, so that minute water droplets may be generated. In such a case, the sublimation substance may be solidified with the minute water droplets as nuclei and then may become particles. According to the above-described exemplary embodiment, the wafer contamination caused by these mechanisms can also be suppressed. Further, as the gas-phase sublimation substance within the processing chamber 81 is decreased, the possibility that the sublimation substance may be solidified and become the particles is also decreased. Thus, as the end of the sublimation processing is approaching, the inside of the processing chamber may be cooled by decreasing a temperature of the purge gas which is being supplied. As a result, a time taken until the second wafer transfer mechanism 62 or wafers of a next set of a room temperature is carried in can be shortened, so that productivity of the drying processing can be improved. For the purpose, an experiment may be conducted to investigate a correlation between a timing for decreasing the temperature of the purge gas and the generation amount of the particles, and the timing for decreasing the temperature of the purge gas may be determined based on the result of this experiment to be stored in the control device 100. During the drying processing, the control device 100 controls a non-illustrated gas temperature control device (a heater or a cooler) provided at the gas line 77 based on the stored timing.

Moreover, according to the above-described exemplary embodiment, since the internal space of the processing chamber 81 is partitioned into the multiple sections 86 vertically separated from each other by the partition plates 87, the flow of the purge gas having a relatively high flow velocity and having strong directivity toward the gas exhaust port 82 from the gate valve 7 is generated within each section 86. Accordingly, the gas of the sublimation substance removed from the wafer W can be exhausted to the gas exhaust port 82 more smoothly.

In addition, according to the above-described exemplary embodiment, since the partition plates 87 are provided between the vertically adjacent wafers W, the gas of the sublimation substance generated from one of the wafers W may not come into a direct contact with a bottom surface of another wafer W located above the corresponding wafer W. Therefore, it may not happen that the sublimation substance is solidified on the bottom surface of the corresponding wafer W located above, so that the bottom surface of the corresponding wafer W can be suppressed from being contaminated.

Moreover, according to the above-described exemplary embodiment, since the heater 88 is provided at each partition plate 87, the multiple wafers W can be heated uniformly, so that uniformity of the batch processing can be improved.

Though it is desirable to provide the partition plates 87, it may also be possible not to provide them. In such a case, as depicted in FIG. 4, for example, plate-shaped water holding members 92 horizontally protruded from the two opposite sidewalls 81a of the processing chamber 81 toward the central portion of the internal space of the processing chamber 81 may be provided in multiple levels in the form of shelves. The transversal sectional plan view of FIG. 4 shows a state in which a peripheral portion of a single sheet of wafer W is supported by a corresponding pair of left and right wafer supporting members 92.

In the modification example shown in FIG. 4, since the internal space of the processing chamber 81 is partitioned into multiple sections by the wafers W and the wafer supporting members 92, the purge gas discharged from the gas discharge holes can be made to flow at a relatively high flow velocity in the direction along the front surfaces of the wafers W. In this case, it is desirable to install the wafer supporting members 92 such that the wafers W are placed as close to the valve body 73 of the closed gate valve 7 as possible. With this configuration, the purge gas discharged from the gas discharge holes 74 of the valve body 73 can be introduced into gaps between the neighboring wafers W more smoothly.

In case of employing the configuration shown in FIG. 4, the heaters provided at the partition plates 87 in the configuration shown in FIG. 2 and FIG. 3 may be installed at a wall of the processing chamber 81.

Further, in the configuration without providing the partition plates 87 as shown in FIG. 4, it may be desirable that the wafers W are supported by the wafer supporting members 92 with the front surfaces (device formation surfaces) thereof facing downwards. In this case, the wafer supporting members 92 may be configured to support a region, where the devices are not formed, at a peripheral portion of the front surface (first surfaces) of each wafer W. If the front surfaces of the wafers W face upwards in the configuration without providing the partition plates 87, a foreign substance, which might be generated within the processing chamber when an abnormality of the processing occurs, may fall on the front surfaces of the wafers W, resulting in contamination of devices on the wafers W. Thus, by placing the wafers W with their front surfaces facing downwards, occurrence of such contamination can be greatly reduced.

In the above-described exemplary embodiment, the purge gas is discharged from the gas discharge holes 74 provided at the valve body 73 of the gate valve 7. Alternatively, as depicted in FIG. 5 and FIG. 6, the gas may be discharged from vertically elongated gas discharge pipes 94 respectively provided at a left and a right side of the gate valve 7. Multiple gas discharge holes 96 are provided at each gas discharge pipe 94 at an interval therebetween in the vertical direction. As schematically illustrated in FIG. 6, the gas is discharged from the gas discharge holes 96 located at a certain height position into the gap 90b between the bottom surface of the wafer W and the partition plate 87 located thereunder, and the gas is the gas discharged discharged from the gas discharge holes 96 located at a height position lower than the corresponding gas discharge holes 96 into the gap 90a between the top surface of another wafer W and the partition plate 87 located thereabove (this configuration is the same as that of the gas discharge holes 74 provided at the valve body 73 of the gate valve 7).

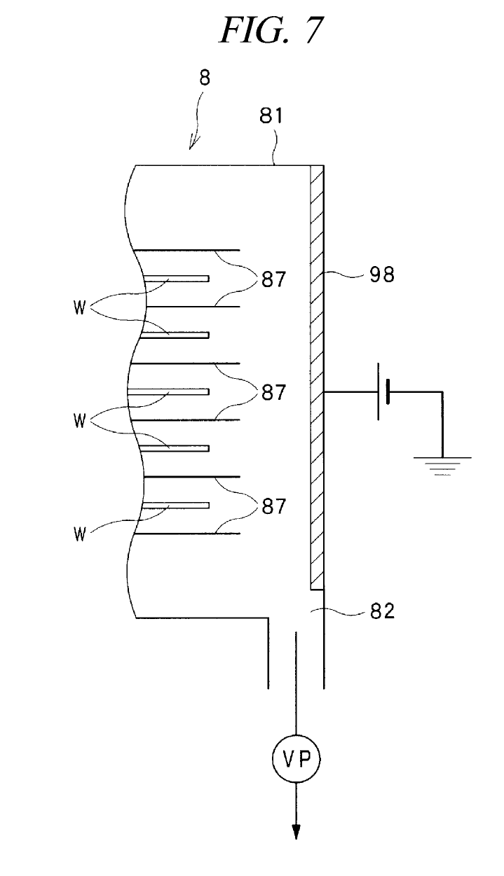

As schematically illustrated in FIG. 7, an electric dust collecting device 98 configured to attract and capture an electrically charged foreign substance contained in the gas of the sublimation substance by an electrostatic force may be provided near the gas exhaust port 82, for example, at the rear wall of the processing chamber 81. The electric dust collecting device 98 may be configured to attract either a positively charged foreign substance or a negatively charged foreign substance.

In the above description, the sublimation processing unit 8 is configured as the batch type processing unit configured to process the multiple wafers W at the same time. However, the sublimation processing unit 8 may be a single-wafer type processing unit configured to process the wafers W one by one. In such a case as well, by generating the flow of the purge gas near the front surface of each wafer W in the direction along the corresponding front surface of the wafer W, the contamination of the wafers W can be suppressed.

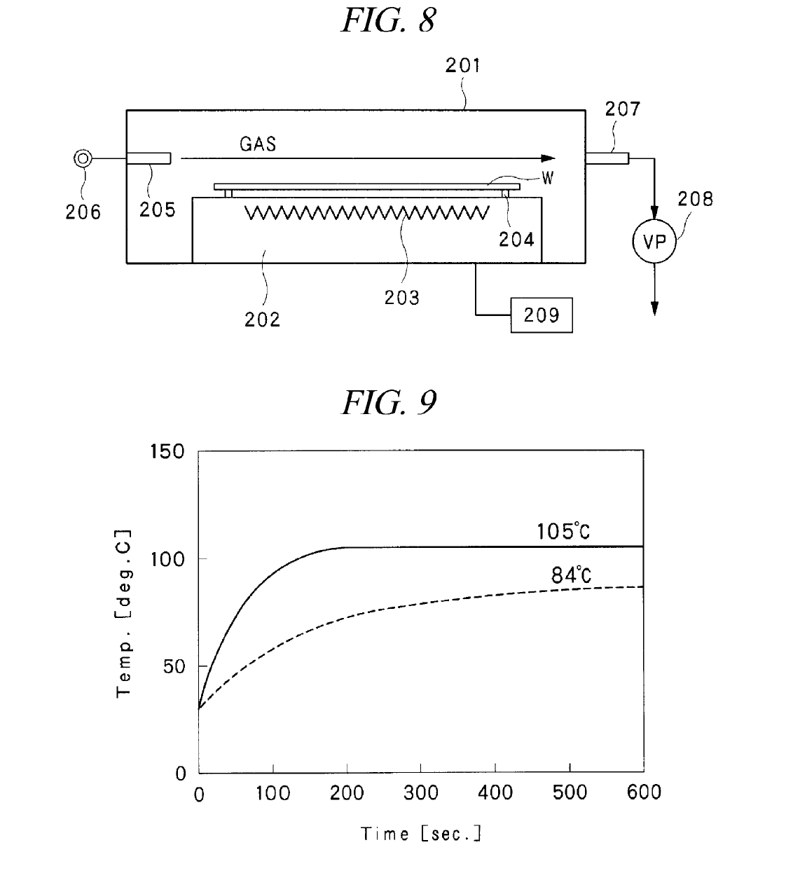

Now, another exemplary embodiment (referred to as “second exemplary embodiment”) will be explained with reference to FIG. 8 and FIG. 9.

When coating a sublimation substance on a three-dimensional integrated circuit or on a wafer having a front surface on which an irregularity of a high aspect ratio is formed, the sublimation substance solution needs to be reached deep into the inside of a recess sufficiently. For the purpose, it is found out in a research by the present inventors that two requirements need to be satisfied: (1) a state in which a thick liquid film of a sublimation substance solution is formed on a front surface (first surface) of a processing target object (substrate) such as a wafer needs to be maintained and (2) the sublimation substance solution needs to be dried rapidly after coating the sublimation substance.

As an example, to achieve the requirement (1), by reducing a rotation speed of the processing target object when supplying the sublimation substance solution onto the front surface of the processing target object while rotating the processing target object, it may become difficult for a centrifugal force to act on the liquid film of the sublimation substance solution. Instead, it may be also possible to form a puddle (liquid film) of the sublimation substance solution on the front surface of the processing target object without rotating the processing target object.

To achieve the requirement (2), by increasing a temperature of the sublimation substance solution via the processing target object, a solvent constituting the sublimation substance solution is made to be evaporated rapidly. By way of example, the processing target object, having the top surface on which the liquid film of the sublimation substance solution is formed, may be heated by a heat plate provided under the processing target object. Alternatively, it may be also possible to heat the processing target object by discharging a heated liquid or a heated gas to the processing target object from a nozzle provided under the processing target object. Still alternatively, the processing target object and the sublimation substance solution may be heated by a heat plate or a heating lamp (e.g., a LED lamp) provided above the processing target object. Still alternatively, the sublimation substance solution may be heated by discharging a heated gas (e.g., dry air or a nitrogen gas) to the processing target object from a nozzle provided above the processing target object. In case of using the nozzle provided above the processing target object, it may be desirable to use a circular plate-shaped nozzle having a multiple number of discharge holes at a bottom surface thereof. By using such a circular plate-shaped nozzle, the sublimation substance solution can be suppressed from being washed off the front surface of the processing target object due to a local collision of a high-pressure gas with the liquid film of the sublimation substance solution.

To meet the requirement (2), a hood surrounding a space above the processing target object may be provided, and the processing target object and the sublimation substance solution may be heated by supplying a heated gas into the hood. At this time, by evacuating a space under the processing target object, the evaporated solvent of the sublimation substance solution can be removed from a space around the processing target object.

Now, an appropriate method for sublimating the solid-state thick sublimation substance, which is attached to the first surface of the processing target object by achieving the requirements (1) and (2), will be explained. In the following description, a single-wafer type processing unit is used, for example.

As depicted in FIG. 8, a wafer W as the processing target object is placed on a heat plate 202 provided within a processing chamber 201. The heat plate 202 has a heater (heating unit) 203 embedded therein. Multiple proximity pins 204 (or protrusions) as the substrate holding unit are provided on a top surface of the heat plate 202. A gas nozzle 205 is provided at one side of the processing chamber 201 (at a position outside an edge of the wafer W). The gas nozzle (gas discharge hole) 205 is configured to discharge a gas (e.g., a nitrogen gas, clean dry air, or the like) supplied from a gas supply mechanism 206 into the processing chamber 201. The gas nozzle 205 and the gas supply mechanism 206 constitute a gas supply unit. A gas exhaust port 207 is provided at the other side of the processing chamber 201. The inside of the processing chamber 201 is evacuated by a vacuum pump 208 connected to the gas exhaust port 207. An operation of the apparatus shown in FIG. 8 is controlled by a control device 209.

As the inside of the processing chamber 201 is suctioned by the vacuum pump 208, the inside of the processing chamber 201 is set in a decompressed state having an internal pressure ranging from, by way of non-limiting example, 10 Pa to several tens of Pa. A narrow gap (clearance) is formed between a top surface of the heat plate 202 and a bottom surface of the wafer W by the proximity pins 204 provided on the top surface of the heat plate 202. Accordingly, when the inside of the processing chamber 201 is evacuated, attachment of the wafer W to the top surface of the heat plate 202 can be suppressed.

The gas is discharged toward the wafer W from the gas nozzle 205 in a direction substantially parallel to the front surface (first surface) of the wafer W. The discharged gas flows across the inside of the processing chamber, and then, is exhausted from the gas exhaust port 207 provided at the opposite side to the gas nozzle 205. The gas supplied into the processing chamber 201 enters the gap between the top surface of the heat plate 202 and the bottom surface (second surface) of the wafer W. Accordingly, heat conduction from the heat plate 202 to the wafer W via the gas serving as a heat transfer medium is performed, so that heating efficiency of the wafer W by the heat plate 202 is improved. Further, when the gas supply from the gas nozzle 205 is not performed, the heat conduction from the heat plate 202 to the wafer W may only be achieved by heat radiation having relatively low efficiency.

The gas discharged from the gas nozzle 205 flows near the first surface of the wafer W in a direction along the first surface of the wafer W. Accordingly, the gas supplied from the gas nozzle 205 not only improves the heating efficiency of the wafer W as stated above, but it also serves as a purge gas which forces a sublimation gas, which is generated as the sublimation substance attached to the front surface (top surface) of the wafer W is sublimated, out of the space above the wafer W. Here, any kinds of gases may be used as long as they do not hamper the sublimation reaction. It is desirable that the gas has high heat conductivity. If there is a gas which accelerates the sublimation reaction of the sublimation substance, such a gas may be used.

A previously heated gas may be discharged from the gas nozzle 205. Accordingly, the heating efficiency can be improved.

It is desirable that the discharge of the gas from the gas nozzle 205 is begun before the sublimation reaction is started. Since the temperature rise of the wafer W can be achieved rapidly by the heat conduction through the gas, the sublimation processing (drying processing) can be ended in a short time period.

Now, reference to FIG. 9, an experiment conducted to investigate an effect of the supply of the gas from the gas nozzle 205 will be discussed with reference to a graph of FIG. 9. A horizontal axis of the graph indicates an elapsed time after the wafer W is placed on the heat plate 202, and a vertical axis represents an actual temperature of the wafer W. When the gas is not supplied from the gas nozzle 205, the inside of the processing chamber 201 is vacuum-evacuated by the vacuum pump 208 such that the internal pressure of the processing chamber 201 becomes 10 Pa. A set temperature of the heat plate 202 is 120° C. While maintaining the vacuum-evacuation condition constantly by the vacuum pump 208, the gas is supplied from the gas nozzle 205 at a flow rate where the internal pressure of the processing chamber 201 rises up to 60 Pa by the supply of the gas.

In the graph of FIG. 9, a temperature variation of the wafer W in the case of not performing the gas supply from the gas nozzle 205 is indicated by a dashed line, and a temperature variation of the wafer W in the case of performing the gas supply is indicated by a solid line. When the gas supply is performed, the temperature rise of the wafer W is found to be faster and a time required for the temperature of the wafer W to be stabilized is found to be shorter.

As clearly seen from the above experimental result, the sublimation processing can be completed in a short time period by performing the gas supply. From the viewpoint of improving the heating efficiency of the wafer W, it is desirable that the supply flow rate of the gas is larger. As the supply flow rate of the gas increases, however, the internal pressure of the processing chamber 201 is increased. The inside of the processing chamber 201 is vacuum-evacuated to allow the phase transition of the sublimation substance to occur from a solid phase to a gas phase (that is, sublimation) without passing through a liquid phase. For this purpose, the supply amount of the gas needs to be decided to allow the internal pressure of the processing chamber 201 to be maintained lower than a pressure where the sublimation substance has the liquid phase. That is, the supply flow rate of the gas from the gas nozzle 205 needs to be set to be of a value at which a pressure rise around the wafer W causing the sublimation substance to be changed into the liquid phase does not occur and, also, at which the gas exists around the wafer W in an amount (concentration) allowing the heat conduction from the heat plate 202 (heating unit) to the wafer W to be accelerated. Since an appropriate gas flow rate may be differed depending on various parameters of the processing apparatus such as an internal volume of the chamber and processing conditions such as the kind of the sublimation substance and a sublimation processing temperature, it may be desirable to determine the gas flow rate by an experiment based on the above-described point of view of setting the flow rate.

As can be understood from the above description, in the exemplary embodiment described with reference to FIG. 1 to FIG. 7, the purge gas discharged from the gas discharge holes 74 and 96 not only form the gas flow flowing near the front surface (first surface) of each wafer W in the direction along the corresponding front surface, but it also form the gas flow flowing near the rear surface (second surface) of each wafer W in the direction along the corresponding rear surface. Though the heat transfer by the heat radiation is dominant within the decompressed space, by supplying the gas into the decompressed space, this gas also serves as the heat transfer medium, so that the heating efficiency can be greatly improved. By way of example, in the exemplary embodiment shown in FIG. 2 and FIG. 3, the purge gas discharged from the gas discharge holes 74 also functions as the heat transfer medium for the heat transfer from the heater 88 to the wafer W.

The processing target substrate is not limited to the semiconductor wafer, and various other kinds of substrates such as, but not limited to, a glass substrate, a ceramic substrate and so forth may be used.

We claim:

1. A plasma processing apparatus, comprising:
a substrate holding unit configured to hold a substrate having a first surface on which a sublimation substance is coated and a second surface opposite to the first surface;
a processing chamber in which the substrate held by the substrate holding unit is accommodated;
a heating unit configured to heat an inside of the processing chamber to sublimate the sublimation substance coated on the first surface of the substrate; and
a gas supply unit configured to supply a gas into the processing chamber,
wherein the gas supply unit comprises a gas discharge hole configured to discharge the gas, and the gas discharge hole is provided at a position outside an edge of the substrate held by the substrate holding unit and forms a flow of the gas flowing in a direction along the first surface or the second surface of the substrate held by the substrate holding unit.

2. The substrate processing apparatus of claim 1,
wherein the substrate is plural in number and the substrate holding unit is configured to hold the substrates at an interval therebetween in a thickness direction of the substrates, and
the gas discharge hole is plural in number and the gas supply unit comprises the gas discharge holes provided to correspond to each of the substrates such that the flow of the gas is formed with respect to each of the substrates.

3. The substrate processing apparatus of claim 2,
wherein the gas discharge holes of the gas supply unit are provided to correspond to the substrates in one to one correspondence.

4. The substrate processing apparatus of claim 2,
wherein a single gas exhaust port is provided at an opposite side to a side where the gas discharge holes are provided, and
the inside of the processing chamber is suctioned through the single gas exhaust port.

5. The substrate processing apparatus of claim 2,
wherein the substrate holding unit is configured to hold the substrates at the interval therebetween in a vertical direction with a horizontal posture.

6. The substrate processing apparatus of claim 2,
wherein partition plates configured to partition the inside of the processing chamber into multiple sections separated from each other in an arrangement direction of the substrates are further provided,
the partition plates are extended in parallel with the substrates held by the substrate holding unit, and
the substrate holding unit holds one substrate within each of the partitioned sections.

7. The substrate processing apparatus of claim 6,
wherein the heating unit comprises a heater provided at each of the partition plates.

8. The substrate processing apparatus of claim 6,
wherein the substrate holding unit comprises substrate supporting members provided at each of the partition plates to support the second surface of the corresponding substrate from below.

9. The substrate processing apparatus of claim 5,
wherein the substrate holding unit comprises multiple sets of substrate supporting members in a form of a pair of shelves which are extended from two opposite walls of the processing chamber toward a central portion of the processing chamber and configured to support a peripheral portion of the second surface of each substrate.

10. The substrate processing apparatus of claim 5,
wherein a gate valve configured to close an opening through which the substrates are carried into or out of the processing chamber is further provided, and
the gas discharge holes are provided at a valve body of the gate valve.

11. The substrate processing apparatus of claim 1,
wherein the substrate is plural in number and the substrate holding unit is configured to hold the substrates at an interval therebetween in a vertical direction with a horizontal posture while the first surfaces thereof facing downwards.

12. The substrate processing apparatus of claim 1,
wherein the gas supply unit forms the flow of the gas flowing near the first surface of the substrate held by the substrate holding unit in the direction along the first surface of the substrate.

13. The substrate processing apparatus of claim 12,
wherein the heating unit comprises a heat plate placed with a gap from the second surface of the substrate held by the substrate holding unit.

14. The substrate processing apparatus of claim 1,
wherein the gas supply unit forms the flow of the gas flowing near the first surface of the substrate held by the substrate holding unit in the direction along the first surface and the flow of the gas flowing near the second surface of the substrate held by the substrate holding unit in the direction along the second surface.

15. The substrate processing apparatus of claim 4,
wherein a control unit configured to control an operation of the gas supply unit is further provided, and
the control unit controls the gas supply unit to supply the gas into the processing chamber at a flow rate where a pressure rise around the substrates, which causes the sublimation substance coated on the first surfaces of the substrates to be changed into a liquid phase, does not occur and where the gas exists around the substrates in an amount allowing heat conduction from the heating unit to the substrates to be accelerated.

16. The substrate processing apparatus of claim 1,
wherein a control unit configured to control an operation of the gas supply unit is further provided, and
the control unit controls the gas supply unit to discharge the gas before sublimation of the sublimation substance coated on the substrate held by the substrate holding unit is begun.

17. The substrate processing apparatus of claim 1,
wherein a control unit configured to control an operation of the gas supply unit is further provided, and
the control unit changes a supply flow rate of the gas supplied into the processing chamber from the gas supply unit based on a generation amount of a sublimation gas generated as the sublimation substance coated on the substrate held by the substrate holding unit is sublimated.

18. The substrate processing apparatus of claim 1,
wherein a gas temperature control unit configured to adjust a temperature of the gas supplied into the processing chamber from the gas supply unit and a control unit configured to control an operation of the gas temperature control unit are further provided, and
the control unit controls the gas temperature control unit to decrease the temperature of the gas supplied into the processing chamber from the gas supply unit as an end of a sublimating processing is approaching.

19. A substrate processing method, comprising:
placing, in a processing chamber, a substrate having a first surface on which a sublimation substance is coated and a second surface opposite to the first surface;
heating the substrate to sublimate the sublimation substance coated on the first surface of the substrate; and
forming, by discharging a gas from a gas discharge hole provided at a position outside an edge of the substrate within the processing chamber, a flow of the gas in a direction along the first surface or the second surface of the substrate placed in the processing chamber.

20. The substrate processing method of claim 19,
wherein the substrate is plural in number, and the placing of the substrate in the processing chamber comprises arranging the substrates at an interval therebetween in a vertical direction with a horizontal posture while the first surfaces thereof facing downwards.
